(19) United States
(12) Patent Application Publication
(10) Pub. No.: US 2026/0052742 A1
(43) Pub. Date: Feb. 19, 2026

(54) IC Package SoC Edges Recess Structure to Reduce Hybrid Bond Stresses for Molded Chip-on-Wafer

(71) Applicant: Apple Inc., Cupertino, CA (US)

(72) Inventors: Yi Xu, Boise, ID (US); Yeguang Xue, San Jose, CA (US); Chi Nung Ni, Foster City, CA (US); Jie-Hua Zhao, Cupertino, CA (US); Vidhya Ramachandran, Cupertino, CA (US)

(21) Appl. No.: 18/807,855

(22) Filed: Aug. 16, 2024

(51) Int. Cl. H01L 23/00; H01L 21/306; H01L 21/56; H01L 23/31; H01L 23/538; H01L 25/065; H01L 29/06

(52) U.S. Cl. CPC H01L 24/08; H01L 23/5383; H01L 23/562; H01L 24/80; H01L 24/97; H10D 62/117; H01L 21/306; H01L 21/561; H01L 23/3107; H01L 25/0655; H01L 2224/08235; H01L 2224/80895; H01L 2224/80896; H01L 2224/97

(57) ABSTRACT

Electronic packages, die structures and methods of fabrication are described in which a recess is formed by removing material from the edges and corners of a die that may increase the risk of non-bonding or delamination. In an embodiment, a die includes a recess with a width that extends from a perimeter edge to a recessed edge, and a depth that extends from a top surface to a recess floor. In some embodiments, the recess is filled with gap fill material. In other embodiments, the recess is not filled with gap fill material.

### BACKGROUND

### Field

Embodiments described herein relate to semiconductor packaging, more particularly to forming recesses for directly bonded structures.

### Background Information

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, vertical integration of die in SiP structures has evolved into 2.5D solutions and 3D solutions. In 2.5D solutions the multiple dies may be flip chip bonded on an interposer that may include through vias as well as fan out wiring. Various 3D solutions exist. In one implementation multiple dies may be stacked on top of one another on an SiP substrate, and connected with off-chip wire bonds or solder bumps. In other traditional 3D solutions hybrid bonding using wafer on wafer (WoW) or chip on wafer (CoW) techniques is utilized. In a WoW solution, the top and bottom device area dimensions are exactly matched, and each layer is restricted to one technology node. In a CoW solution multiple top wafers (chips) can be integrated onto the same bottom wafer with defined area and technology node.

Hybrid bonding including metal-metal and oxide-oxide bonding has generally been adopted as a suitable technology for mass production of high-density input/output (I/O) chips with ultra-small pad pitches. A traditional hybrid bonding sequence includes three main operations including oxide-to-oxide initial bonding at room temperature, heating to close dishing gap, and then further heating to compress metal-to-metal bonds. After the hybrid bonding process there can be follow up processing and device finishing operations depending upon the particular application. Modern integrated circuit (IC) fabrication techniques commonly utilize molding compound such as epoxy molding compound to encapsulate the hybrid bonded dies for various reasons including to protect brittle material from mechanical damage and to smooth out a surface to facilitate downstream wafer-level processing.

### SUMMARY

Embodiments describe electronic packages and methods in which a recess is formed in a die to mitigate bonding interface stress concentrations related to the direct bonding process. In an embodiment, a recess may be formed in a die (e.g., etching, laser grooving, etc.), where a width of the recess may extend from a perimeter edge to a recessed edge of the die, and a depth of the recess may extend a top surface to a recess floor of the die. In one embodiment, gap fill material fills the recess. In another embodiment, gap fill material does not fill the recess.

### BRIEF DESCRIPTION OF THE DRAWINGS

FIG. 1A is a cross-sectional side view illustration of an electronic package with a die that includes a sloped recess filled with gap fill material in accordance with embodiments.

FIG. 1B is a cross-sectional side view illustration of an electronic package with a die that includes a substantially flat recess filled with gap fill material in accordance with embodiments.

FIGS. 2A-2C are schematic top layout views of example arrangements of a plurality of dies in accordance with embodiments.

FIG. 3 is a flow chart of a first method for forming a recess filled with gap fill material in accordance with embodiments.

FIGS. 4A-4D are schematic cross-sectional side view illustrations of a first method for forming a recess filled with gap fill material in accordance with embodiments.

FIG. 5 is a flow chart of a second method for forming a recess filled with gap fill material in accordance with embodiments.

FIGS. 6A-6D are schematic cross-sectional side view illustrations of a second method for forming a recess filled with gap fill material in accordance with embodiments.

FIG. 7A is a cross-sectional side view illustration of an electronic package with a die that includes a sloped recess in accordance with embodiments.

FIG. 7B is a cross-sectional side view illustration of an electronic package with a die that includes a substantially flat recess in accordance with embodiments.

FIG. 8 is a flow chart of a method for forming a recess in accordance with embodiments.

FIGS. 9A-9C are schematic cross-sectional side view illustrations of a method for forming a recess in accordance with embodiments.

### DETAILED DESCRIPTION

As a result of the direct bonding process (e.g., fusion bonding, hybrid bonding, etc.) in which a die is directly bonded to an interposer, for example, it has been observed that the die may have a certain level of intrinsic warpage, where such warpage may create high stress concentrations at the edges and corners of the die. In some instances, the high stress concentrations at the edges and corners of the die cause the bonds formed during the direct bonding process to become unbonded (e.g., delamination). Even in instances where the direct bonding process does not cause delamination, the bonds may be weakened so that subsequent stresses from downstream fabrication processes may ultimately cause delamination. For example, high peeling stress concentrations may form when the bonded structure is trying to bend due to thermal or mechanical loadings, such as with epoxy molding compound (“EMC”) expansion at elevated temperatures. Additionally, high shear stress concentrations may form as the bonded structure tries to shrink or expand together with other packaging and system components (e.g., substrate, printed circuit board, etc.). In embodiments, a recess may be formed in the die in order to shift the high stress concentrations from the edges and corners, where the die may be especially vulnerable to delamination, to an inner region, where the die may be less vulnerable to delamination. In this way, the recess may help to reduce the risk of hybrid bonding or fusion bonding delamination at the edges and corners of the die. In some embodiments, gap fill material (e.g., EMC, etc.) applied during the encapsulation process may fill the recess. In other embodiments, gap fill material applied during the encapsulation process may not fill the recess.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “to”, “between”, and “on” as used herein may refer to a relative position of one layer with respect to other layers. One layer “on” another layer or bonded “to” or in “contact” with another layer may be directly in contact with the other layer or may have one or more intervening layers. One layer “between” layers may be directly in contact with the layers or may have one or more intervening layers.

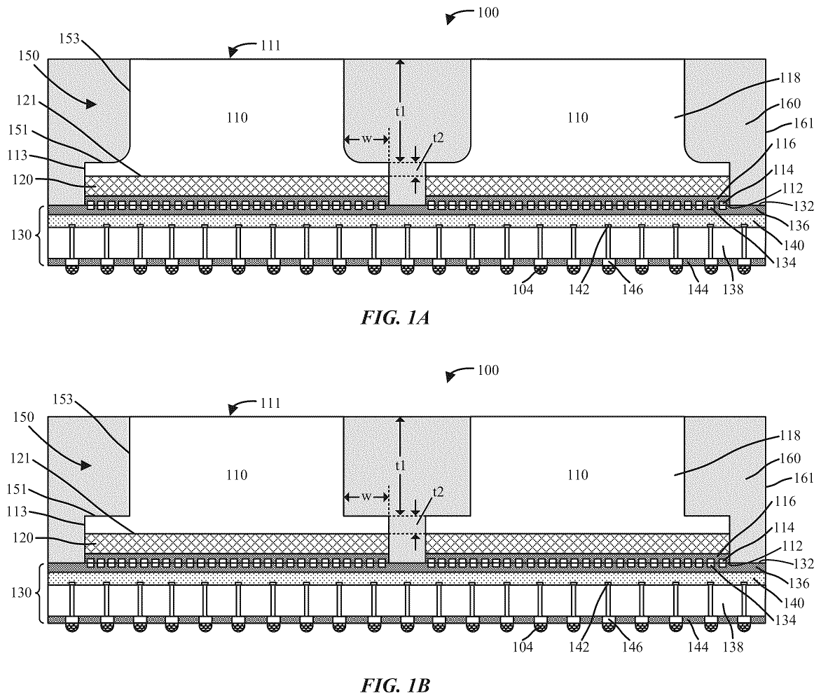

Referring now to FIGS. 1A-1B, FIG. 1A is a cross-sectional side view illustration of an electronic package with a die that includes a sloped recess filled with gap fill material in accordance with embodiments; FIG. 1B is a cross-sectional side view illustration of an electronic package with a die that includes a substantially flat recess filled with gap fill material in accordance with embodiments. Electronic package 100 may include a plurality of dies bonded to an electronic component. For example, in FIG. 1A, electronic package 100 includes a plurality of dies, such as die 110, and electronic component 130. Die 110 may include semiconductor layer 118 and back-end-of-the-line (“BEOL”) build-up structure 120. Semiconductor layer 118 may include a bulk silicon substrate, silicon-on-insulator (“SOI”) substrate, etc. and may also include an epitaxial device layer. It should be noted that silicon is an exemplary substrate material and that other semiconductor substrate materials are contemplated. BEOL build-up structure 120 may include electrical routing as is customary, as well as optional metal sealing structures (e.g., seal rings) to function as both a physical barrier from moisture and impurity ingress, as well as to provide mechanical integrity. In instances where BEOL build-up structure 120 includes metal sealing structures (e.g., seal rings), such metal sealing structures may be located underneath recess floor 151. Further, BEOL build-up structure 120 may include a plurality of metal wiring layers and dielectric layers, referred to as interlayer dielectrics (“ILD”) as is common in microelectronic manufacturing.

In further reference to FIG. 1A, electronic component 130 can be a variety of components such as a second die, an interposer, etc. Electronic component 130 may include semiconductor layer 138 (which can also be a bulk layer formed of silicon) and BEOL build-up structure 140. Alternatively, semiconductor layer 138 can be substituted with another bulk material, such as glass. BEOL build-up structure 140 may include electrical routing, an optional seal ring, and optional die-to-die routing between other components that may be bonded to electronic component 130. In addition, a plurality of through vias 142 (e.g., through silicon vias, through glass vias, etc.) can extend through the semiconductor layer 138 and backside layer 144 to make contact with terminals 146, onto which solder bumps 104 (which can also be solder tips) may be placed.

Still referring to FIG. 1A, die 110 may be directly bonded to electronic component 130. Direct bonding may be accomplished using suitable techniques, such as fusion bonding (e.g., dielectric-dielectric bonds) or hybrid bonding (e.g., metal-metal bonds and dielectric-dielectric bonds), where the dielectric materials used by hybrid and/or fusion bonding can be inorganic-based or organic-based materials. For example, die 110 may include bonding surface 112, a plurality of metal bond pads 114, and dielectric bonding layer 116 on BEOL build-up structure 120. Similarly, electronic component 130 may include bonding surface 132, a plurality of metal bond pads 134, and dielectric bonding layer 136 on BEOL build-up structure 140. Dielectric bonding layers 116, 136 may be formed of an insulating material, such as an oxide (e.g., silicon oxide, silicon nitride, silicon carbon nitride, etc.). Further, bonding surfaces 112, 132 may be planarized (e.g., chemical mechanical polishing (“CMP”)) to facilitate fusion or hybrid bonding, where such planarized bonding surfaces may be directly bonded to one another at (and diffused across) a bonding interface.

It has been observed that the direct bonding processes (e.g., fusion bonding, hybrid bonding, etc.) may cause residual stress in the BEOL build-up structures and dielectric bonding layers of a die. The residual stress may in turn cause a certain level of intrinsic warpage in the die, which may weaken or even break the bonds formed during the direct bonding process, especially the bonds near the edges or corners of the die where stress concentrations may be high. In addition, it has been observed that subsequent downstream processes may add to the high stress concentrations near the edges or corners of the die. For example, as a result of the encapsulation process, molding compound material (e.g., epoxy molding compound) may cause high peeling stress concentrations near the edges of corners of the die when applying thermal loads to an electronic package due to the mismatched coefficient of thermal expansion between the molding compound material and the die it encapsulates. In embodiments, a recess may be formed in the die to shift the high stress concentrations from the edges and corners of the die to an inner area or region where the direct bonds may be stronger and the die stiffer.

In further reference to FIG. 1A, die 110 includes recess 150 to mitigate bonding interface stress concentrations near the corners and edges of die 110. Recess 150 may be formed by any suitable method, such as etching (e.g., wet etch, dry etch, etc.), laser grooving, etc. Further, the shape of recess 150 may depend on the method used to form the recess. In one example, the sloped shape of recess 150 in FIG. 1A may be formed by laser grooving or wet etching, which is generally isotropic so that the etchants remove material uniformly in all directions. In another example, the L-shape of recess 150 in FIG. 1B may be formed in die 110 by dry etching, which is highly anisotropic and allows for precise control over the profile of the etch. In addition, for the L-shaped of recess illustrated in FIG. 1B, recess floor 151 is substantially flat and orthogonal to perimeter edge 113. Further, gap fill material 160 (e.g., epoxy molding compound (“EMC”), etc.) may laterally surround the plurality of dies and fill the spaces between dies. In the examples of FIGS. 1A-1B, gap fill material 160 fills recess 150, extending from bonding surface 132 to top surface 111 of die 110. In such instances, gap fill material 160 may form part of diced edge 161 of electronic package 100 after singulation.

Still referring to FIG. 1A, recess 150 has a width, w, that extends from perimeter edge 113 to recess edge 153. In some embodiments, the width, w, that extends from perimeter edge 113 to recess edge 153 is between 200 μm to 1 mm. Further, recess 150 has a depth that extends through a partial thickness of die 110, t1, from top surface 111 to recess floor 151, where a remaining thickness of die 110, t2, extends from recess floor 151 to top surface 121 of BEOL build-up structure 120. In some instances, the remaining thickness of the die after forming the recess relates to the risk of delamination. In some embodiments, the remaining thickness, t2, is between 30-100 μm. In one example, during reliability risk tests in which electronic packages undergo sub-zero temperature cycles, it has been observed that the delamination risk may be reduced by approximately 14% as compared to conventional methods where the remaining thickness is approximately 100 μm, and reduced by approximately 56% as compared to conventional methods where the remaining thickness is approximately 30 μm. In another example, during assembly risk tests in which electronic packages undergo “reflow” temperature cycles, it has been observed that the delamination risk may be reduced by approximately 64% as compared to conventional methods where the remaining thickness is approximately 100 μm, and reduced by approximately 99.99% as compared to conventional methods where the remaining thickness is approximately 30 μm. It should be noted that the remaining thickness, t2, may not be so thin so as to potentially damage the sensitive low-k dielectric layers in BEOL build-up structure 120.

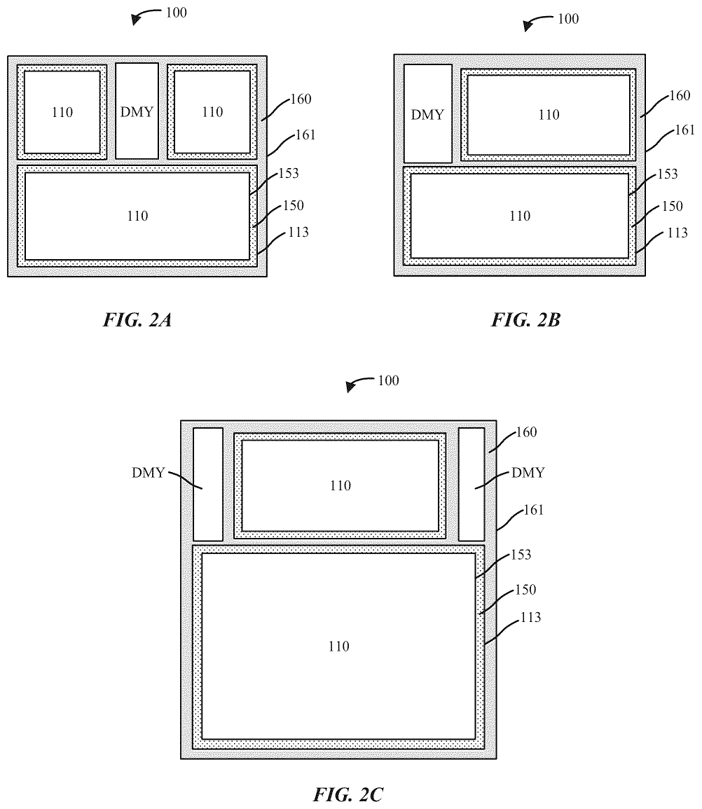

Referring now to FIGS. 2A-2C, FIG. 2A is a schematic top layout view of a first example arrangement of a plurality of dies in accordance with embodiments; FIG. 2B is a schematic top layout view of a second example arrangement of a plurality of dies in accordance with embodiments; FIG. 2C is a schematic top layout view of a third example arrangement of a plurality of dies in accordance with embodiments. In embodiments, recess 150 may be formed around a perimeter of each of the plurality of dies, respectively. For example, as illustrated in FIG. 2A, recess 150 surrounds a perimeter of die 110, where recess 150 may be defined by perimeter edge 113 and recess edge 153 of die 110. In addition, it is to be appreciated that the particular arrangement of dies in FIG. 2A is exemplary and that embodiments are applicable to a variety of other arrangements that may include a different number of dies and dummy features, DMY, such as the example arrangements illustrated in FIGS. 2B-2C, although other configurations are also contemplated.

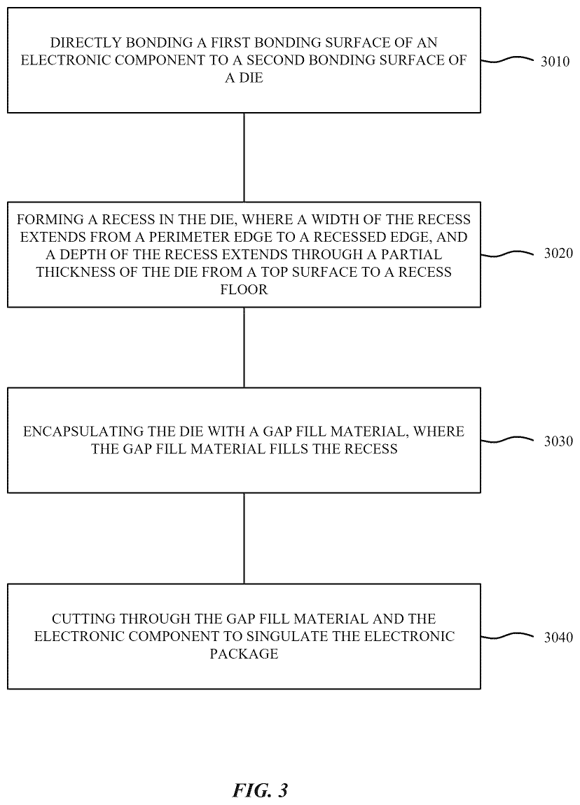

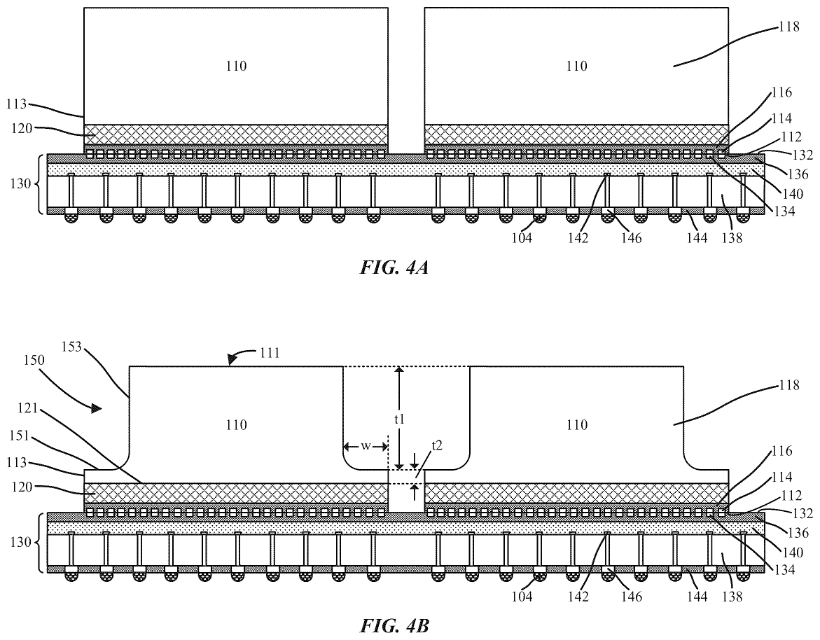

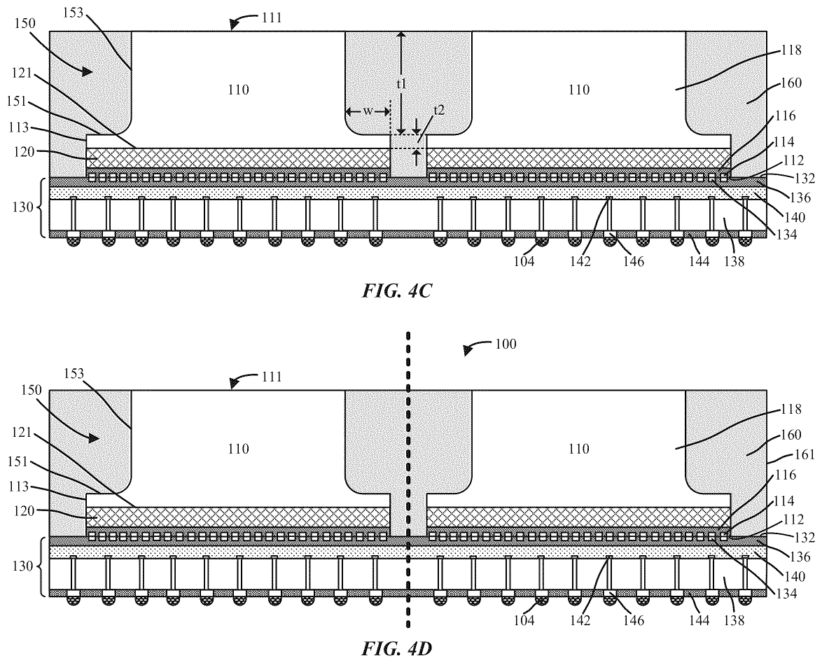

Referring now to FIG. 3 and FIGS. 4A-4D, FIG. 3 is a flow chart and FIGS. 4A-4D are schematic cross-sectional side view illustrations of a first method for forming a recess filled with gap fill material in accordance with embodiments. In the interest of clarity and conciseness, the method of FIG. 3 is described concurrently with the illustrations of FIGS. 4A-4D. At operation 4010, bonding surface 112 of die 110 may be directly bonded (e.g., fusion bonded, hybrid bonded, etc.) to bonding surface 132 of electronic component 130. At operation 4020, recess 150 may be formed to mitigate the stress concentrations that may have accumulated near the edges or corners of die 110 during the direct bonding process. In the example illustrated in FIG. 4B, recess 150 is formed by masking a center portion of each of the plurality of dies 110 and wet etching the unmasked portions of each of the plurality of dies 110 to remove the edges and corners. Since wet etching is generally isotropic, the etchants remove material uniformly in all directions and form a sloped recess, similar to the example of FIG. 1A. In some embodiments, recess 150 may be formed by dry etching, which is highly anisotropic and, as a result, may form an L-shaped recess 150, where recess floor 151 is substantially flat and orthogonal to perimeter edge 113, similar to the example of FIG. 1B. Further, the etching process may be performed to control the width, w, of recess 150, which extends from perimeter edge 113 to recess edge 153. Similarly, the etching process may be performed to control the depth of recess 150, which extends through a partial thickness of die 110, t1, from top surface 111 of die 110 to recess floor 151. In embodiments, the remaining thickness of die 110, t2, which extends from recess floor 151 to top surface 121 of BEOL build-up structure 120, may relate to the risk of delamination. In one example, the risk of delamination may be significantly reduced where the remaining thickness of die 110, t2, is approximately 30 μm. At operation 4030, an encapsulation process may be performed where gap fill material 160 (e.g., EMC) may laterally surround the plurality of dies and fill the spaces between dies, where the encapsulation process may then be followed by a grinding operation to expose the dies. In the example of FIG. 4C, gap fill material 160 fills recess 150. At operation 4040, a cutting operation (e.g., dicing, etc.) may be performed to cut through gap fill material 160 and electronic component 130 to singulate electronic package 100. In such instances, gap fill material 160 may form part of diced edge 161 of electronic package 100.

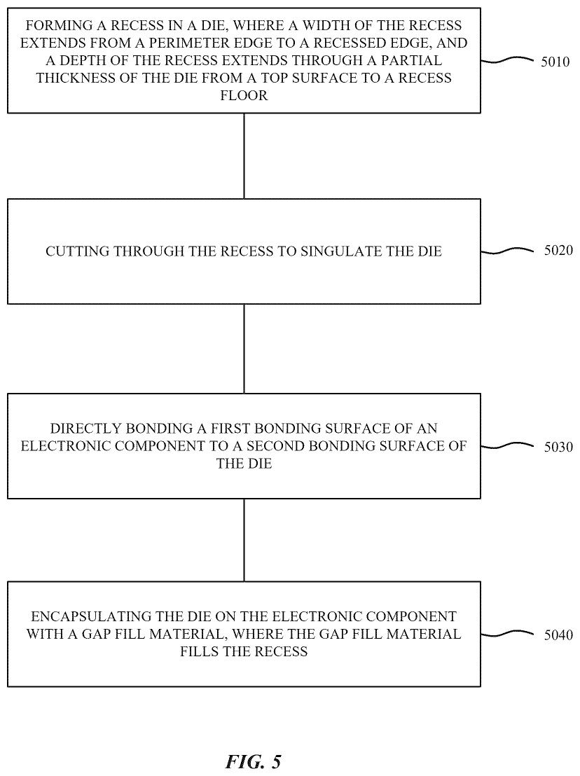

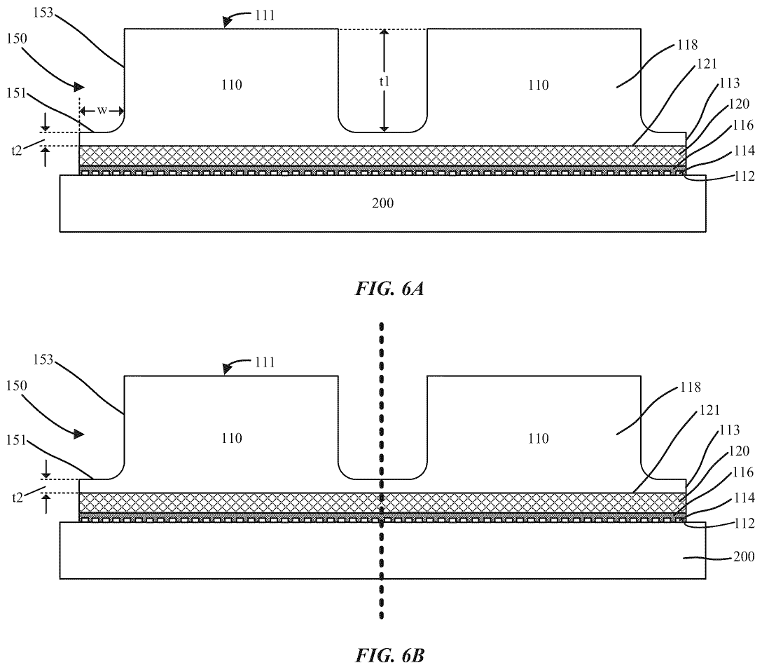

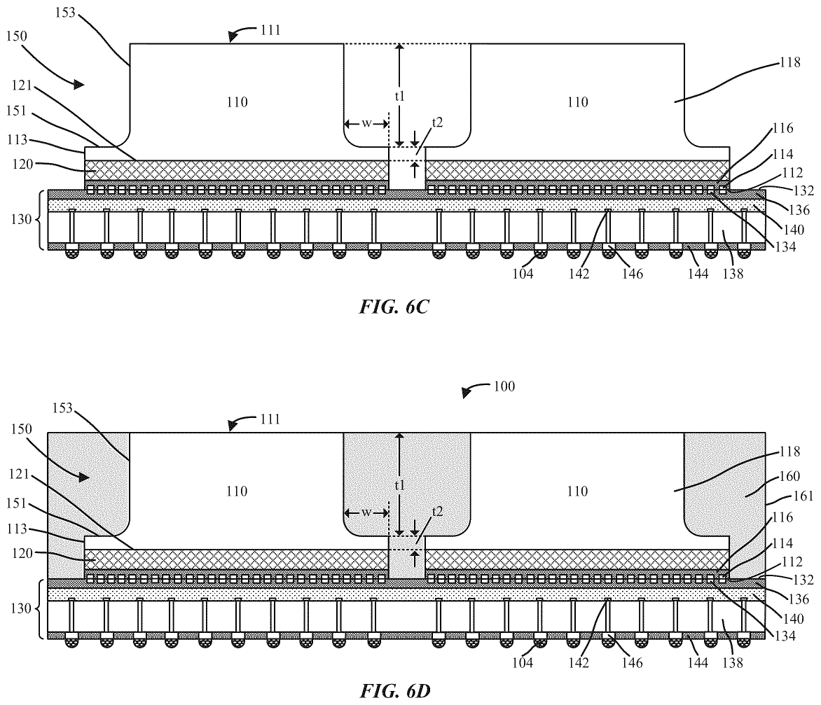

Referring now to FIG. 5 and FIGS. 6A-6D, FIG. 5 is a flow chart and FIGS. 6A-6D are schematic cross-sectional side view illustrations of a second method for forming a recess filled with gap fill material in accordance with embodiments. In the interest of clarity and conciseness, the method of FIG. 5 is described concurrently with the illustrations of FIGS. 6A-6D. At operation 5010, recess 150 may be formed by backside laser grooving, etching (e.g., wet etch, dry etch, etc.), etc., before the singulation of the plurality of dies at operation 5020, where such operations may be carried out on carrier wafer 200. In instances where recess 150 is formed by laser grooving or wet etching, recess 150 may be sloped, similar to the example of FIG. 1A. In instances where recess 150 is formed by dry etching, recess 150 may be L-shaped, similar to the example of FIG. 1B. Further, the formation of recess 150 may be performed to control its width, w, as well as its depth, which extends from through a partial thickness of die 110, t1, from top surface 111 to recess floor 151. Similar to the example of FIG. 1A, the remaining thickness of die 110, t2, which extends from recess floor 151 to top surface 121 of BEOL build-up structure 120, also relates to the risk of delamination, where it has been observed that a remaining thickness, t2, of approximately 30 μm may significantly reduce the risk of delamination. At operation 5030, the diced and recessed dies may be directly bonded (e.g., fusion bonded, hybrid bonded, etc.) to electronic component 130. At operation 5040, an encapsulation process may be performed where gap fill material 160 (e.g., EMC) may laterally surround the plurality of dies and fill the spaces between dies, where the encapsulation process may be followed by a grinding operation to expose the dies. In the example of FIG. 6C, gap fill material 160 fills recess 150. Further, in a cutting operation (e.g., dicing, etc.) to singulate electronic package 100, gap fill material 160 may form part of diced edge 161 of electronic package 100.

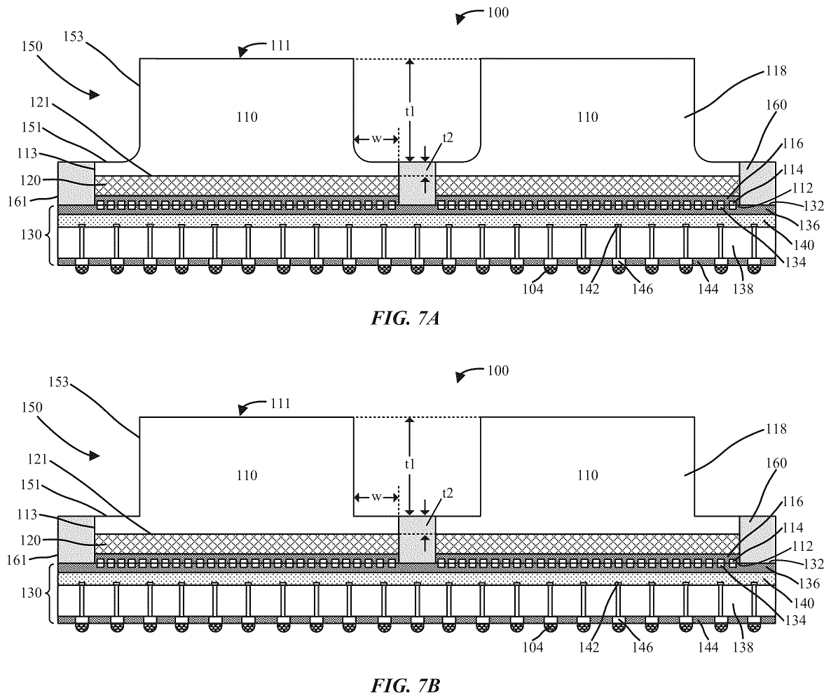

Referring now to FIGS. 7A-7B, FIG. 7A is a cross-sectional side view illustration of an electronic package with a die that includes a sloped recess in accordance with embodiments; FIG. 7B is a cross-sectional side view illustration of an electronic package with a die that includes a substantially flat recess in accordance with embodiments. The embodiments described in FIGS. 7A-7B are substantially similar to the embodiments described in FIGS. 1A-1B with one difference being that gap fill material 160 in FIGS. 7A-7B does not fill recess 150. In reference to FIG. 7A, electronic package 100 includes a plurality of dies, such as die 110, and electronic component 130. Die 110 may include semiconductor layer 118 (e.g., silicon substrate, epitaxial layer, etc.) and BEOL build-up structure 120 with optional metal sealing structures (e.g., seal rings) as well as a plurality of metal wiring and dielectric layers (e.g., ILD), similar to the example described in FIG. 1A. In instances where BEOL build-up structure 120 includes metal sealing structures (e.g., seal rings), such metal sealing structures may be located underneath recess floor 151. Further, electronic component 130 (e.g., die, interposer, etc.) may include semiconductor layer 138 (e.g., silicon, glass, etc.), BEOL build-up structure 140 (e.g., electrical routing, seal ring, die-to-die routing, etc.) as well as a plurality of through vias 142 (e.g., through silicon vias, through glass vias, etc.) that extend through the semiconductor layer 138 and backside layer 144 to make contact with terminals 146, onto which solder bumps 104 (which can also be solder tips) may be placed, similar to the example described in FIG. 1A. Further, die 110 may include a bonding surface 112, a plurality of metal bond pads 114, and dielectric bonding layer 116 on BEOL build-up structure 120. In addition, electronic component 130 may include bonding surface 132, a plurality of metal bond pads 134, and dielectric bonding layer 136 on BEOL build-up structure 140. In embodiments, bonding surface 112 of die 110 may be directly bonded (e.g., hybrid bonded, fusion bonded etc.) to bonding surface 132 of electronic component 130.

In further reference to FIG. 7A, die 110 includes recess 150 that may be formed by any suitable method such as laser grooving, etc., where recess 150 may be sloped as illustrated in FIG. 7A (similar to the example of FIG. 1A) or L-shaped as illustrated in the example of FIG. 7B (similar to the example of FIG. 1B). Further, recess 150 has a width, w, that extends from perimeter edge 113 to recessed edge 153, and a depth that extends through a partial thickness of die 110, t1, from top surface 111 to recess floor 151, similar to the example of FIG. 1A. In addition, the remaining thickness of die 110, t2, which extends from recess floor 151 to top surface 121 of BEOL build-up structure 120 relates to the risk of delamination in the same manner described in the example of FIG. 1A. Further, similar to the examples illustrated in FIGS. 1A-1B, the examples illustrated in FIGS. 7A-7B include gap fill material 160 that may laterally surround the plurality of dies and fill the spaces between dies. However, in contrast to the examples illustrated in FIGS. 1A-1B, gap fill material 160 does not fill recess 150, as illustrated in the examples of FIGS. 7A-7B. For example, in FIG. 7A, gap fill material 160 extends from bonding surface 132 to recess floor 151. In such instances, gap fill material 160 may form part of diced edge 161 of electronic package 100 after singulation.

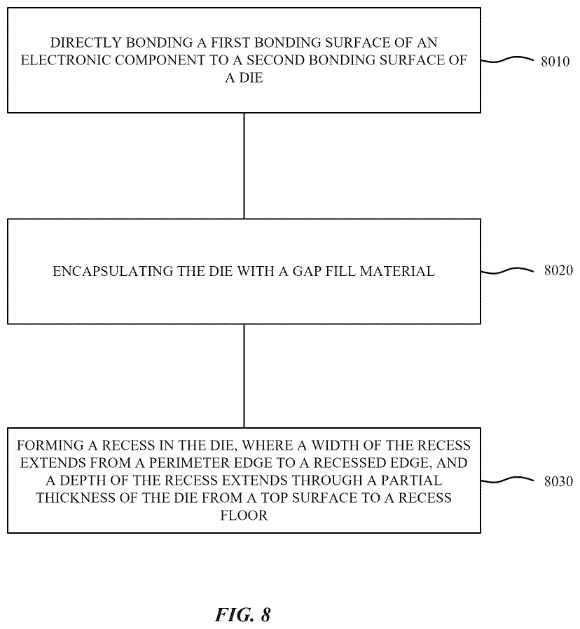

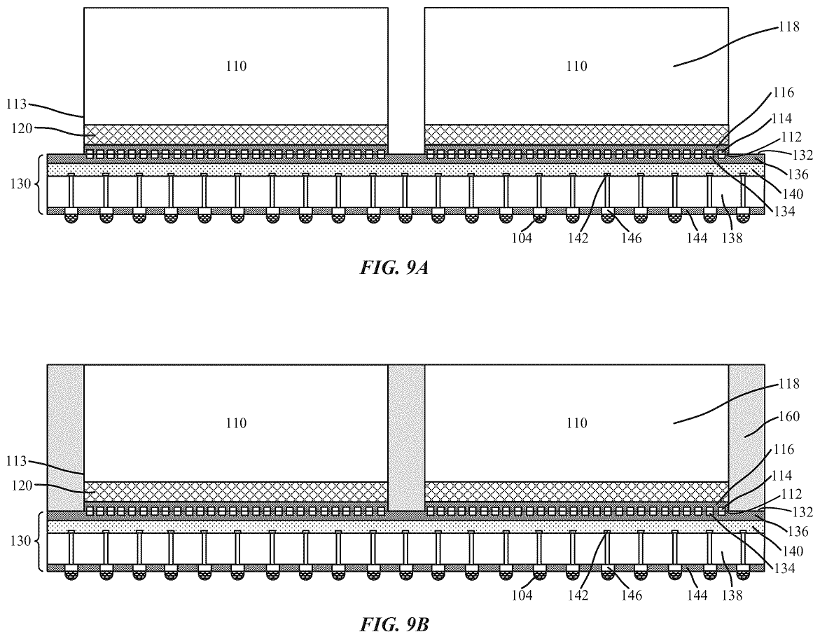

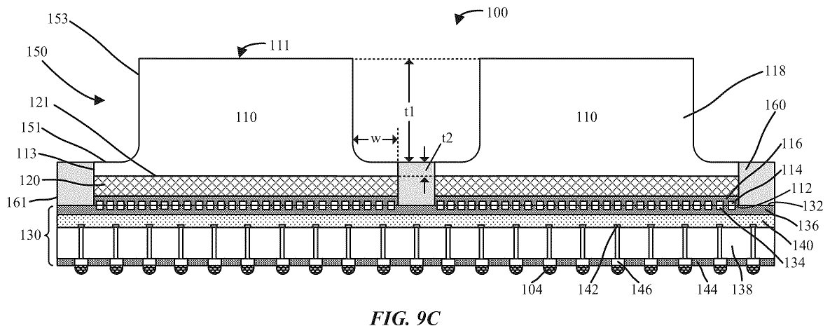

Referring now to FIG. 8 and FIGS. 9A-9C, FIG. 8 is a flow chart and FIGS. 9A-9C are schematic cross-sectional side view illustrations of a method for forming a recess in accordance with embodiments. In the interest of clarity and conciseness, the method of FIG. 8 is described concurrently with the illustrations of FIGS. 9A-9C. At operation 8010, bonding surface 112 of die 110 may be directly bonded (e.g., fusion bonded, hybrid bonded, etc.) to bonding surface 132 of electronic component 130. At operation 8020, an encapsulation process may be performed where gap fill material 160 (e.g., EMC) may laterally surround the plurality of dies and fill the spaces between dies, which can be followed by a grinding operation to expose the dies. Unlike the embodiments described in FIGS. 1A-1B in which the recesses are formed before encapsulation, the recesses in the embodiments described in FIG. 7A-7B are formed after encapsulation. As such, at operation 8030, a laser grooving operation may be performed to simultaneously form recess 150 and to remove gap fill material 160 to create the “empty” recess illustrated in FIG. 9B, as opposed to the “filled” recess illustrated in FIGS. 1A-1B. In further reference to FIG. 9B, gap fill material 160 extends vertically from bonding surface 132 of electronic component 130 to recess floor 151, where gap fill material 160 may form part of diced edge 161 of electronic package 100 after singulation. Similar to the embodiments described in FIGS. 1A-1B, recess 150 has a width, w, that extends from perimeter edge 113 to recess edge 153, as well as a depth that extends from through a partial thickness of die 110, t1, from top surface 111 to recess floor 151. Also, similar to the embodiments described in FIGS. 1A-1B, the remaining thickness of die 110, t2, relates to the risk of delamination, where it has been observed that a remaining thickness of approximately 30 μm may significantly reduce the risk of delamination while maintaining the integrity of BEOL build-up structure 120.

In utilizing the various aspects of the embodiments, it would become apparent to one skilled in the art that combinations or variations of the above embodiments are possible for forming a recess for directly bonded structures. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic package comprising:
an electronic component including a first bonding surface;
a die including a recess and a second bonding surface, the second bonding surface bonded directly to the first bonding surface, wherein a width of the recess extends from a perimeter edge to a recessed edge, and a depth of the recess extends through a partial thickness of the die from a top surface to a recess floor; and
a gap fill material that laterally surrounds the die and vertically extends from the first bonding surface of the electronic component to at least the recess floor of the die.

2. The electronic package of claim 1, wherein the electronic component is an interposer, and the die includes a back-end-of-the-line (“BEOL”) build-up structure and a semiconductor layer on the BEOL build-up structure, wherein the recess is in the semiconductor layer.

3. The electronic package of claim 1, wherein the first bonding surface is hybrid bonded with the second bonding surface.

4. The electronic package of claim 1, wherein the recess floor is sloped.

5. The electronic package of claim 1, wherein the recess floor is substantially flat and orthogonal to the perimeter edge.

6. The electronic package of claim 1, wherein the gap fill material fills the recess.

7. The electronic package of claim 1, wherein the gap fill material is included as part of a diced edge of the electronic package.

8. A method of forming an electronic package comprising:
directly bonding a first bonding surface of an electronic component to a second bonding surface of a die;
forming a recess in the die, wherein a width of the recess extends from a perimeter edge to a recessed edge, and a depth of the recess extends through a partial thickness of the die from a top surface to a recess floor;
encapsulating the die with a gap fill material, wherein the gap fill material fills the recess; and
cutting through the gap fill material and the electronic component to singulate the electronic package.

9. The method of claim 8, wherein the electronic component is an interposer, and the die includes a back-end-of-the-line (“BEOL”) build-up structure and a semiconductor layer on the BEOL build-up structure, wherein the recess is in the semiconductor layer.

10. The method of claim 8, wherein the first bonding surface is hybrid bonded with the second bonding surface.

11. The method of claim 8, wherein the recess floor is either sloped, or substantially flat and orthogonal to the perimeter edge.

12. The method of claim 8, wherein the gap fill material is included as part of a diced edge of the electronic package.

13. A method of forming an electronic package comprising:
directly bonding a first bonding surface of an electronic component to a second bonding surface of a die;
encapsulating the die with a gap fill material; and
forming a recess in the die, wherein a width of the recess extends from a perimeter edge to a recessed edge, and a depth of the recess extends through a partial thickness of the die from a top surface to a recess floor;
wherein the gap fill material laterally surrounds the die and vertically extends from the first bonding surface of the electronic component to the recess floor of the die.

14. The method of claim 13, wherein the electronic component is an interposer, and the die includes a back-end-of-the-line (“BEOL”) build-up structure and a semiconductor layer on the BEOL build-up structure, wherein the recess is in the semiconductor layer.

15. The method of claim 13, wherein the first bonding surface is hybrid bonded with the second bonding surface.

16. The method of claim 13, wherein the recess floor is sloped, or substantially flat and orthogonal to the perimeter edge.

17. The method of claim 13, wherein the gap fill material is included as part of a diced edge of the electronic package.

18. A method forming an electronic package comprising:
forming a recess in a die, wherein a width of the recess extends from a perimeter edge to a recessed edge, and a depth of the recess extends through a partial thickness of the die from a top surface to a recess floor;
cutting through the recess to singulate the die;
directly bonding a first bonding surface of an electronic component to a second bonding surface of the die; and
encapsulating the die on the electronic component with a gap fill material, wherein the gap fill material fills the recess.

19. The method of claim 18, wherein the electronic component is an interposer, and the die includes a back-end-of-the-line (“BEOL”) build-up structure and a semiconductor layer on the BEOL build-up structure, wherein the recess is in the semiconductor layer.

20. The method of claim 18, wherein the gap fill material is included as part of a diced edge of the electronic package.
